(19) United States
(12) Patent Application Publication
(10) Pub. No.: US 2008/0167827 A1
(43) Pub. Date: Jul. 10, 2008

(54) TWO-STAGE HIGH IMPEDANCE FAULT DETECTION

(76) Inventors: Sara C. McAllister, Ossining, NY (US); Tomasz J. Nowicki, Fort Montgomery, NY (US); Grzegorz M. Swirszez, Ossining, NY (US)

Correspondence Address: WHITHAM, CURTIS & CHRISTOFFERSON, P.C., 11491 SUNSET HILLS ROAD, SUITE 340, RESTON, VA, 20190, US

(21) Appl. No.: 11/620,068

(22) Filed: Jan. 5, 2007

(51) Int. Cl. G01R 31/08; G06F 19/00

(52) U.S. Cl. 702/59

(57) ABSTRACT

A method and apparatus detect and localize of electric faults in electrical power grids and circuit. Readouts from remote sensors are pre-analyzed by remote processor units using pre-defined updateable fast algorithms to make an initial identification of a high impedance electrical fault. Whenever the data is remotely qualified as potentially representing a fault, it is then transmitted to the central processor unit running sophisticated, potentially self-learning, easily modifiable and adaptable algorithms for detailed analysis of the transmitted signal. The central process can request more data from other remote processor units than the one or more remote processor units reporting the potential fault for comparative analysis. The remote processors are provided with limited storage capacity to allow backtracking readouts for a limited period of time.

### BACKGROUND OF THE INVENTION

1. Field of the Invention

The present application generally relates to the detection of high-impedance faults in electrical power grids and, more particularly, to the detection and localization of faults in electrical power grids and circuits by the pre-analysis of data from sensors on remote units and transmitting remotely qualified data as potentially representing a fault to a central processing unit which performs a detailed analysis of the transmitted data.

2. Background Description

High impedance faults are costly, dangerous to the equipment and a threat to human life. There is a huge diversity of phenomena classified as high impedance faults. These include, but are not limited to, a downed line, a tree branch touching a line, a broken insulator, and improper installation. As a result, there is no accepted scientific knowledge about the nature of high impedance fault detection.

Electrical power grids are extremely complicated, making the detection and localization of a high impedance fault difficult and problematic. Current methods of detection include circuit breakers tripping, readout from meters at the substation by human operators, and a telephone call from someone who noticed a fault. Interestingly, the last of these methods, e.g., a telephone call, is the most common method by which faults are detected and located. There have been attempts to use local sensors that automatically make a decision and either raise an alarm or disconnect a part of the grid. These attempts have proven to be unsatisfactory due to the lack of processing power and the ability to flexibly adapt to the specifics of a particular environment.

### SUMMARY OF THE INVENTION

According to the present invention, there is provided an innovative solution to the high impedance fault detection problem by analyzing the data from remote sensor units deployed over the network locally, and after pre-qualification, transmitting all the parts of readouts potentially indicating a fault to a powerful central processing unit. Associated with each of the remote sensor units are remote processing units which implement fast, rudimentary algorithms to pre-analyze sensor readouts. Whenever the readouts are identified as indicators of a potential fault at a remote sensor unit, the transmission of data to the central processor unit is initiated. The pre-processing and pre-qualifying of the data at the remote sensor units limits the amount of data that needs to be transmitted to the central processor unit. The second stage of the analysis is performed as the central processor unit, which has at its disposal much more processing power than the remote sensor units. The central processing unit performs a comparative analysis of readouts from multiple locations in the network.

There are many advantages to the approach taken by the present invention. These include automatic detection and localization of high impedance faults, high accuracy, fast response, flexibility and adaptability. Modifications and updates to the algorithms implemented by the central processor unit are inexpensive and easy on the central processor unit, but very costly and complicated on remote units.

### BRIEF DESCRIPTION OF THE DRAWINGS

The foregoing and other objects, aspects and advantages will be better understood from the following detailed description of a preferred embodiment of the invention with reference to the drawings, in which:

FIG. 1 is a high level block diagram illustrating the general concept of the two-stage high impedance fault detection system according to the invention;

FIG. 2 is a more detailed block diagram illustrating multiple remote sensor units and their associated remote processing units and the pre-processing performed by the remote processing units;

FIG. 3 is a block diagram of a remote processing unit and the central server;

FIG. 4 is a block and data flow diagram illustrating the process of the two stage HIF detection and recognition according to the invention; and

FIG. 5 is a block and data flow diagram illustrating the organization and operation of the central processor unit which constitutes the second stage of the two-stage high impedance fault detection system according to the invention.

### DETAILED DESCRIPTION OF A PREFERRED EMBODIMENT OF THE INVENTION

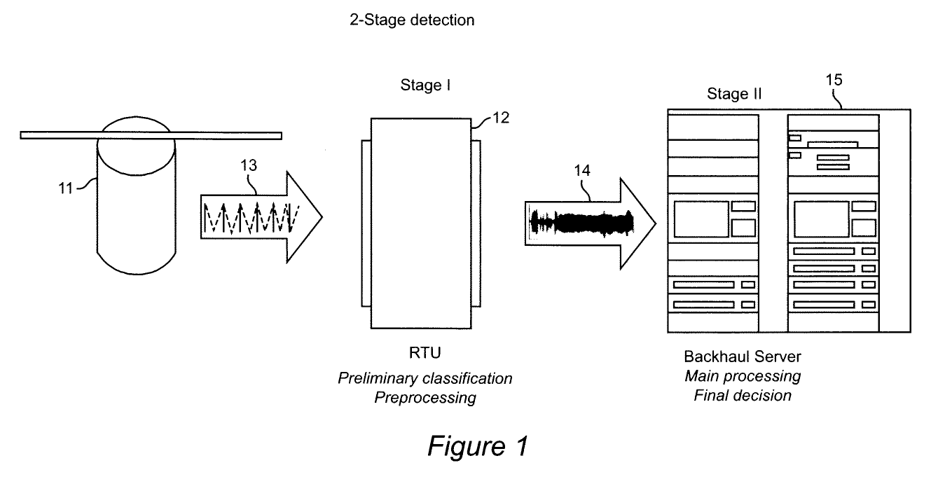

Referring now to the drawings, and more particularly to FIG. 1, there is illustrated in block diagram from the basic concept of the two-stage high impedance fault detection system according to the invention. The first stage comprises a collection of voltage/current or other types of sensors deployed over the power grid. A single one of the sensors 11 is illustrated for the purposes of this description, but it will be understood that many such sensors are deployed over the entire grid. Next to each sensor there is located a remote processing unit which performs a pre-analysis of the signal from its associated sensor. Again, a single one of the remote processor units 12 is illustrated for the purposes of this description. Each of the remote processor units is capable of sampling, pre-processing and pre-qualifying a signal 13 from its associated sensor. The signal readouts from the sensor are constantly monitored and analyzed online by its remote processor unit. Fast algorithms of data analysis are implemented on each remote processor unit. These algorithms are capable of identifying a readout that is not typical. These algorithms may be remotely updateable and make an initial identification of a potential fault using a very low reaction threshold. Whenever a readout is identified as not typical, the transmission to the central processor unit is initiated. In FIG. 1, this is illustrated by the data signal 14 transmitted to central processor unit 15, which constitutes the second stage of the two-stage high impedance fault detection system according to the invention. This transmission may be implemented by broadband power line (BPL) technology or by wireless transmission, or a combination of both as will be discussed in more detail hereinafter. The central processor unit 15 analyzes the data further, taking advantage of more resources than are available to the individual remote processing units. The central processor unit runs sophisticated, potentially self-learning, easily modifiable and adaptable algorithms for detailed analysis of the transmitted signals from the remote processor units. Moreover, the central processor unit can be provided with the ability to request more data from other remote processor units than the one or more remote processor units reporting the potential fault for comparative analysis. Therefore, the remote processor units should contain limited storage capacity so as to provide the ability to backtrack the readouts for some limited period of time.

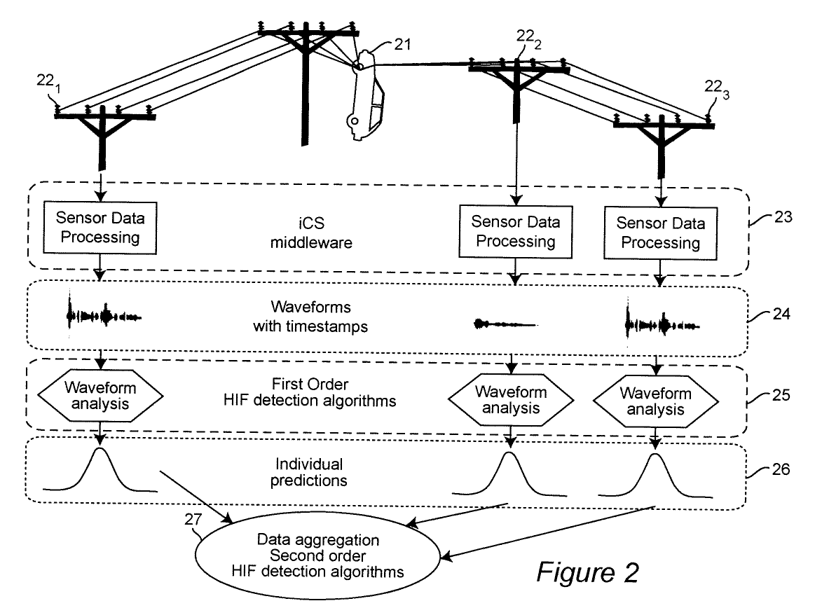

FIG. 2 shows in more detail the processes of the first stage of the two-stage high impedance fault detection system of the invention. In this illustration, a fault 21 is caused by an automobile accident in which the automobile has become entangled in the power lines, and while this is an extreme example, it is but one of many diverse causes of high impedance faults which may occur in an electrical grid. Another example occurred when the gondola of a gas balloon became entangled in power lines during the 2005 annual balloon festival in Albuquerque, N. Mex. In the case of the automobile accident, it is likely that occurrence and location would be reported by a human observer by telephone, for example, but the gas balloon incident occurred in a remote rural area requiring that the location of the accident be found by driving a pickup truck along the lines. More commonly, however, the high impedance fault could be caused by tree limbs, deteriorating insulators, the collapse of a power line pole or support, or the like. In FIG. 2, the fault has occurred between two power line support poles 22, and 222. It will be understood that the power lines extend beyond these two poles, and a further support pole 223 is shown to illustrate this fact. Remote sensor units and their associated remote processor units (not shown) are deployed at each of the support poles. The remote processor units first perform sensor data processing at 23 to generate signal waveforms for analysis. The signal waveforms from the sensors are sampled and time stamped at 24 by the remote processor units, and the signal waveforms are subject to first order high impedance fault detection algorithms at 25. On the basis of this signal analysis, individual predications are generated at 26 by each of the remote processor units.

Only those individual predictions from remote sensor units determined to be not typical are transmitted to the central processor unit. Several remote processor units may be aggregated, as indicated at 27, for transmission of data to the central processor unit for the second stage of fault detection and analysis. This transmission can be by means of broadband power line technology (BPL) or wireless transmission or the combination of the two. For example, several remote processor units can be grouped into a wireless local area network (LAN) which communicates with a transmitter centrally located to that particular wireless local area network. If the technology used is limited to BPL, each remote processor unit would have a connection to the central processor unit to be able to be able to transmit the amount of data equivalent to two to five seconds or more of sampled readout of its associated sensor. Other technologies can be used to transmit the data.

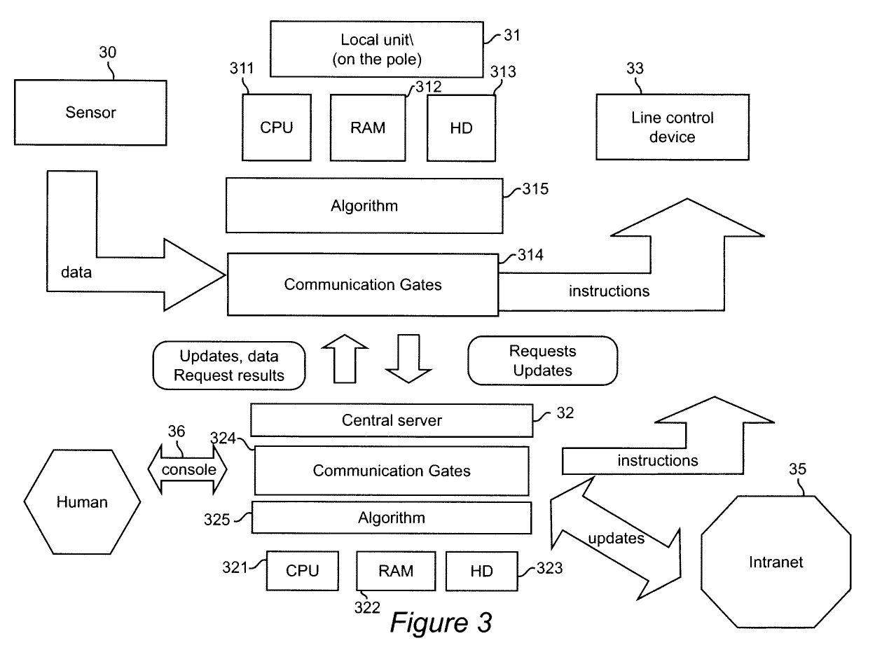

FIG. 3 is a block diagram of a remote processing unit and the central server illustrating the various components of each. Although only one local unit 31 is illustrated, the two stage HIF recognition apparatus consists of a central server 32 and multiple local units. Each of the local unit, like the central server, is a computer but having considerably less computing power than the central server. More particularly, each local unit is a stand alone computer consisting of a central processing unit (CPU) 311, operating memory in the form of a random access memory (RAM) 312 and persistent storage device, such as a hard drive (HD) 313. In addition, each local unit includes communication gates 314 which provide the communication channels for data from an associated sensor 30 and, possibly, instructions to line control devices 33, such as circuit breakers. The communication gates 314 also provide bi-directional communication channels to the central processor 32.

The CPU 311 and the RAM 312 of each local unit runs continuously a recognition/diagnostic program (algorithm) 315 with data input from the sensor 30. Using a local database of past events stored on HD 313 of possible scenarios and the data from the sensor, the algorithm 315 typically results in a (real-) time series of numbers or vectors of numbers which can represent an assessment of the probability or a likelihood of one or more events on the line. When the result of the algorithm indicates normal operation of the line, it is ignored and the algorithm 315 proceeds to calculate the next point of the time series. When a specific threshold is reached (or a resulting vector is in a specific domain) the algorithm sends a signal to the line control device 33 (such as a circuit breaker) to initiate one of predefined actions (such as to isolate a segment of the grid). When another threshold is reached (or the vector enters a different domain), there is generated a signal to the central server 32 demanding one of the following possible actions:
Activate a more powerful recognition algorithm,
Request more data from the central database.

The central server 32 consists of a central processor unit (CPU) 321, operating memory RAM 322 and persistent storage HD 323. Communication gates 324 provide communication channels to multiple local units, line control devices and an external grid of computers via an intranet 35. In addition, the communication gates 324 provide an interface to a human controlled console 36, which typically includes a keyboard, mouse, display and printer (not shown). The central server 32 has more computational power and stores larger databases than the local units. It also runs algorithms 325 which may request and use data from many local units. The algorithms may also request human intervention or more information from the external network. After obtaining a request from a local unit, the central server 32 may initiate action of a line device or return results to a local unit or ignore the result of the algorithm (if it presents a “normal situation diagnosis”). In addition, the central server 32 may monitor the local units and update their databases and algorithms.

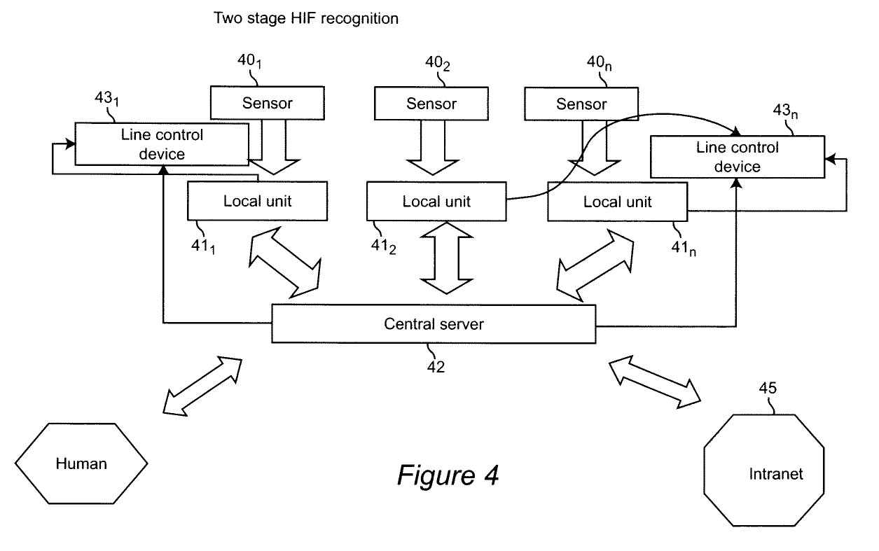

FIG. 4 is a block and data flow diagram of the process that is implemented on the remote processing unit shown in FIG. 3. The method is to employ in a continuous way on each local unit 41₁, 41₂, . . . , 41ₙ algorithms and databases with multiple possible outcomes. Depending on the data (signals) from the sensors 40₁, 40₂, . . . , 40ₙ, if the result of the algorithms ignored and the algorithm 315 proceeds to calculate the next point of the time series. When a specific threshold is reached (or a resulting vector is in a specific domain) the algorithm sends a signal to the line control device 33 (such as a circuit breaker) to initiate one of predefined actions (such as to isolate a segment of the grid). When another threshold is reached (or the vector enters a different domain), there is generated a signal to the central server 32 demanding one of the following possible actions:
Activate a more powerful recognition algorithm,
Request more data from the central database.

The central server 32 consists of a central processor unit (CPU) 321, operating memory RAM 322 and persistent storage HD 323. Communication gates 324 provide communication channels to multiple local units, line control devices and an external grid of computers via an intranet 35. In addition, the communication gates 324 provide an interface to a human controlled console 36, which typically includes a keyboard, mouse, display and printer (not shown). The central server 32 has more computational power and stores larger databases than the local units. It also runs algorithms 325 which may request and use data from many local units. The algorithms may also request human intervention or more information from the external network. After obtaining a request from a local unit, the central server 32 may initiate action of a line device or return results to a local unit or ignore the result of the algorithm (if it presents a “normal situation diagnosis”). In addition, the central server 32 may monitor the local units and update their databases and algorithms.

FIG. 4 is a block and data flow diagram of the process that is implemented on the remote processing unit shown in FIG. 3. The method is to employ in a continuous way on each local unit 41₁, 41₂, . . . , 41ₙ algorithms and databases with multiple possible outcomes. Depending on the data (signals) from the sensors 40₁, 40₂, . . . , 40ₙ, if the result of the algorithms indicates a normal situation, the local units do nothing. If the result of the algorithms indicates a specific HIF, the local unit(s) activate a line device 43₁, . . . , 43ₙ to isolate the cause of the HIF. If the result of the algorithms is indecisive, the local units request support from the central server 42 in the form of additional computational power, stronger algorithms, larger databases, more information from other local units and delegation of the decision (ignore, activate, investigate) to the central server 42. The central server 42 my, in turn, request human intervention/evaluation and/or more external resources (from intranet 45 or the Internet).

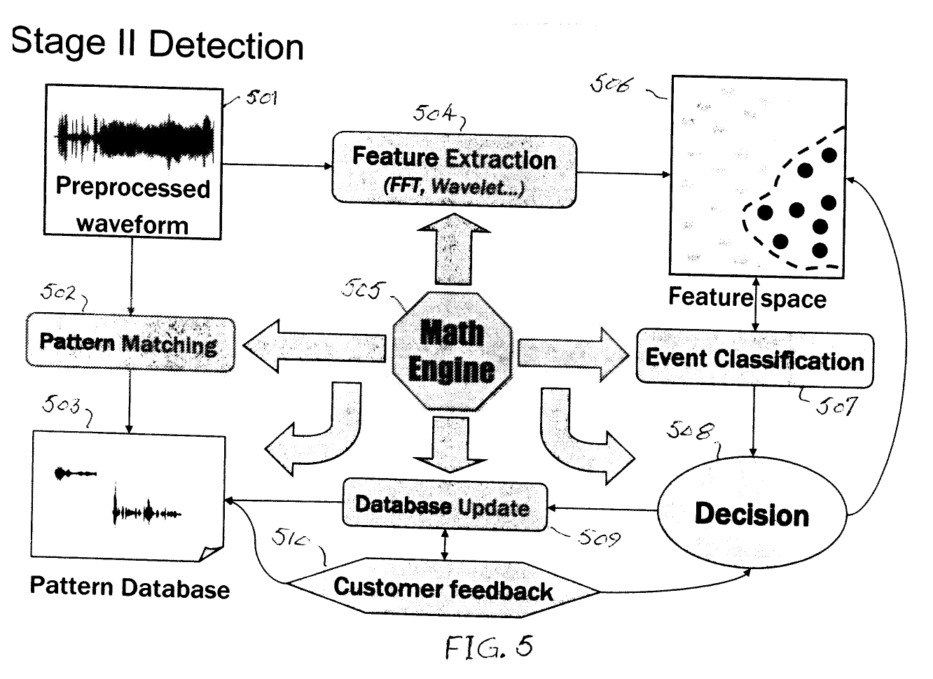

FIG. 5 is a block and data flow diagram showing the organization and operation of the central processor unit which constitutes the second stage of the two-stage high impedance fault detection system. The pre-processed waveform from a remote processing unit is received at 501. This waveform is subjected to two types of analysis. First, the waveform is subjected to a pattern matching analysis at 502 by accessing a pattern database 503. Second, the waveform is subject to feature extraction at 504. This feature extraction may include a fast Fourier transform (FFT) analysis, wavelet extraction, and the like. Both the pattern matching and feature extraction are performed by a math engine 505 (part of the CPU). The data generated by feature extraction 504 is stored in a feature space database 506. Data from this database is accessed and subject to event classification 507 by the math engine 505 and, based on the event classification, a decision 508 is made (i.e., ignore, activate, investigate). Depending on the decision, databases 503 and 506 are updated; in the case of database 503, the database update 509 provides a correlation to the pattern database of classified events. Finally, all of this operation is ultimately displayed and under the control of a human operator 510.

While the invention has been described in terms of a single preferred embodiment, those skilled in the art will recognize that the invention can be practiced with modification within the spirit and scope of the appended claims.

Having thus described our invention, what we claim as new and desire to secure by Letters Patent is as follows:

1. A two-stage system for the detection and localization of electric faults in power grids and circuits comprising:
a plurality of remote sensor units deployed throughout a power grid;
a plurality of remote processor units each associated with a corresponding one of said remote sensor units, each of said plurality of remote processor units sampling, pre-processing and pre-qualifying a signal from its associated remote sensor unit and making an initial identification of a not typical condition;
means for transmitting data indicating a not typical condition from one or more remote processor units; and
a central server unit receiving data transmitted from said means for transmitting and analyzing said data to identify and locate a fault condition.

2. The two-stage system recited in claim 1, further comprising at least one line control device controlled by one or more remote processor units to isolate a fault when said initial identification of a not typical condition exceeds a predetermined threshold.

3. The two-stage system recited in claim 2, wherein when the data transmitted of a not typical condition from one or more remote processor units does not exceed said predetermined threshold, a request is made to the central server unit to delegate a decision on the data to the central server unit.

4. The two-stage system recited in claim 2, wherein each of said remote processor units comprises:
a central processing unit (CPU);
an operating memory;
a persistent memory storing a local database of possible scenarios and data from an associated sensor; and
communication channels providing communication of data from the associated sensor, instructions to said line control device, and bi-directional communications with the central server unit, wherein the CPU and operating memory continuously run a recognition/diagnostic program with data input from the associated sensor and the local database.

5. The two-stage system recited in claim 4, wherein the central server unit comprises:
a CPU;
an operating memory;
a persistent memory storing one or more databases;
communication channels providing communication with said plurality of remote processor units; and
a console providing human input and output.

6. The two-stage system recited in claim 5, wherein the communication channels of the central server unit further provide communication with external sources via a network.

7. The two-stage system recited in claim 6, where in the network is selected from an intranet and the Internet.

8. A two-stage method for the detection and localization of electric faults in power grids and circuits comprising the steps of:
deploying a plurality of remote sensor units throughout a power grid;
providing a plurality of remote processor units each associated with a corresponding one of said remote sensor units, each of said plurality of remote processor units sampling, pre-processing and pre-qualifying a signal from its associated remote sensor unit and making an initial identification of a not typical condition;
transmitting data from one or more remote processor units indicating a not typical condition; and
receiving by a central server unit data transmitted from said one or more remote processor units and analyzing said data to identify and locate a fault condition.

9. The two-stage method recited in claim 8, further comprising the step of controlling at least one line control device by one or more remote processor units to isolate a fault when said initial identification of a not typical condition exceeds a predetermined threshold.

10. The two-stage method recited in claim 9, wherein when the data transmitted of a not typical condition from one or more remote processor units does not exceed said predetermined threshold, further comprising the step of requesting the central server unit to make a decision on the transmitted data.
